(19) United States
(12) Patent Application Publication
(10) Pub. No.: US 2003/0059959 A1
(43) Pub. Date: Mar. 27, 2003

(54) Method for fabricating capacitor

(76) Inventor: Kwon Hong, Ichon-shi (KR)

Correspondence Address: Finnegan, Henderson, Farabow,, Garrett & Dunner, L.L.P., 1300 I Street, N.W., Washington, DC, 20005-3315, US

(21) Appl. No.: 10/224,276

(22) Filed: Aug. 21, 2002

(30) Foreign Application Priority Data
Sep. 22, 2001 (KR) 2001-58830

(51) Int. Cl. H01L 21/00; H01L 21/8242

(52) U.S. Cl. 438/3; 438/240; 438/253

(57) ABSTRACT

Disclosed is a method for fabricating a capacitor, which comprises the steps of forming a Pt alloy layer, as a bottom electrode, electrically being in contact with an active region of a semiconductor substrate, oxidizing a surface of the Pt alloy layer to form a conductive oxide layer, forming a dielectric layer on the conductive oxide layer and forming a top electrode on the dielectric layer.

### FIELD OF THE INVENTION

The present invention relates to a method for fabricating a capacitor in a semiconductor device; and, more particularly, to a method for fabricating a capacitor using a Pt alloy as a bottom electrode.

### DESCRIPTION OF THE PRIOR ART

A unit cell of a dynamic random access memory (DRAM), which is usually used in a semiconductor memory device, and a ferroelectric random access memory (FeRAM), which has been recently developed, consists of a set of a transistor and a capacitor.

As integration of the DRAM increases, a size of the unit cell becomes smaller. For example, an area of the unit cell is about 0.5 μm² and an area of the capacitor is below 0.3 μm² in a 256M DRAM. Accordingly, it is difficult to apply a conventional technology for fabricating semiconductor devices in a highly integrated device, such as over 256M memory device.

When a capacitor is formed with a SiO₂ layer, a Si₃N₄ layer or the like, which are conventionally used as a dielectric layer in the DRAM, an area of the capacitor have to be over six times as much as an area of the unit cell in order to obtain a desired capacitance even if a thickness of a dielectric layer is maximally reduced. To solve this problem, a method for expanding a surface area of the dielectric layer has been introduced.

In order to expand the surface area of the dielectric layer in the capacitor, that is, to expand a surface area of a storage node, a stacked capacitor, a trench capacitor or a hemispherical capacitor has been suggested. However, when the conventional dielectric materials, such as a SiO₂ or Si₃N₄ family having a low capacitance is used in the highly integrated memory device over 256M DRAM, there is a limitation to reduce the thickness of the dielectric layer in obtaining the desired capacitance. Also, in order to expand the surface area of the storage node, complicated processes are required so that a fabricating cost increases and a production efficiency decreases. Further, a method to obtain a desired capacitance through the increase of a surface of a storage node in a 3-dimensional structure is hard to be applied in the DRAM device of over 1 Gb.

To solve the above problems, a research of a Ta₂O₅ dielectric layer has been studied in order to replace the SiO₂/Si₃N₄ dielectric layers. However, since a capacitance of the Ta₂O₅ dielectric layer is only two or three times as much as that of the SiO₂/Si₃N₄ dielectric layers, a thickness of the Ta₂O₅ dielectric layer has to be thinner to obtain a desired capacitance and this thin Ta₂O₅ layer causes a leakage current. Namely, it is difficult to employ the Ta₂O₅ dielectric layer in highly integrated memory devices due to the increasing current leakage.

Since it is difficult to use the conventional dielectric materials in the capacitor for over 1 Gb DRAM, a new dielectric layer having a high capacitance is required. If the high dielectric material is used as a dielectric layer, a fabricating process of the capacitor can be simplified because the dielectric layer can be evenly formed. Recently, a (Ba, Sr)TiO₃ (herein, referred to as BST) layer has been developed as the high dielectric layer. A capacitance of the BST layer is much higher than that of the dielectric layers of SiO₂/Si₃N₄ family and the BST layer has a thermally stable characteristic of a SrTiO₃ layer and an excellent electrical characteristic of a BaTiO₃ layer so that the BST layer is suitable for the memory device of over 1G DRAM.

When the high dielectric layer, such as the BST layer or the like, is used in the capacitor, it is difficult to use a polysilicon layer as an electrode due to an oxidation of the polysilicon layer so that noble metals or oxides thereof are used as the electrode. For example, Pt, Ir, Ru, RuO₂, IrO₂ or conductive oxides, such as TiN or the like, are used as the electrode material.

When the high dielectric layer is used in the capacitor, a crystallization process of the dielectric layer is required at a high temperature and in an oxygen atmosphere to obtain a desired capacitance. When a high thermal treatment process for the crystallization is carried out in the oxygen atmosphere, oxygen atoms of the dielectric layer diffuse into the electrode and the diffused oxygen atoms oxidize a surface of a polysilicon plug so that a SiO₂ oxide layer is created. Since the SiO₂ layer is an insulating layer, the electrode is electrically disconnected with the polysilicon plug. Also, when the bottom electrode is contacted to the polysilicon plug, a reaction between the bottom electrode and the polysilicon plug is caused at a temperature of over 250° C. so that a resistance of the boundary between the bottom electrode and the polysilicon plug increases. To solve the above problem, a diffusion barrier layer is formed with a TiN layer.

However, the TiN layer is also oxidized at a high temperature of over 550° C. and in an oxygen atmosphere. Namely, oxygen, which is diffused by passing though a bottom electrode, reacts with the TiN layer so that a TiO₂ insulating layer is formed on a surface of the TiN layer.

FIG. 1 is a cross-sectional view showing a capacitor in a semiconductor device in accordance with the prior art.

Referring to FIG. 1, a storage node contact plug 2 is formed with a polysilicon on the semiconductor substrate 1, which predetermined processes are completed. Ti is deposited on the polysilicon plug 2 and a rapid thermal process is carried out to form a titanium silicide layer 3. Non-reacted Ti is removed by a wet etching process. A titanium nitride layer 4 is formed as a diffusion barrier layer on the titanium silicide layer 3 and a bottom electrode 5 is formed with noble metal, such as Pt or the like. A high dielectric layer 6, such as a STO (SrTiO₃) layer, a BST ((Ba, Sr)TiO₃) layer or the like in the DRAM or a PZT (Pb(Zr, Ti)O₃) layer, a SBT (SrBi₂Ta₂O₉) layer, a SBTN (SrxBi_{2-y}(Ta_{1-z}Nb_{z})209) layer, a BLT (Bi, La)TiO₃) layer or the like in the FeRAM, is formed on the bottom electrode 5.

As mentioned the above, in fabricating a capacitor, a diffusion barrier layer has to protect diffusions of each material and have a high resistance for oxidation in a high thermal treatment process of the dielectric layer. The titanium silicide layer, which has been used as a conventional diffusion barrier layer, can function as the diffusion barrier by a temperature of about 450° C. due to the surface oxygen stuffing. However, when the temperature becomes over 500° C. in the thermal treatment process, oxygen atoms, which are in the high dielectric layer or a ferroelectric layer, diffuse into the bottom electrode and oxidize the titanium nitride layer. Since a TiO₂ layer, which is a low dielectric layer, is created, characteristics of the dielectric layer are deteriorated.

To solve the above problem, a diffusion barrier layer, which has an excellent resistance against oxidation at a high temperature, has to be developed. Recently, amorphous tri-element barrier metal layers, such as TiAlN, TiSiN, TaSiN and the like, have been researched. These layers have higher resistance against oxidation at a temperature of about 50° C. to 100° C. than the TiN layer. However, it is still not an appropriate temperature to obtain a desired capacitance in the high dielectric layer, such as the STO layer, the BST layer or the like, or the ferroelectric layer, such as the PZT layer, the SBT layer, the SBTN layer, the BLT layer or the like. To the desired capacitance in the high dielectric layer or the ferroelectric layer, a diffusion barrier layer, which have a resistance for oxidation at a temperature of over 600° C., are required.

### SUMMARY OF THE INVENTION

It is, therefore, an object of the present invention to provide a method for fabricating a capacitor using a Pt alloy bottom electrode capable of increasing a processing temperature in crystallizing a dielectric layer.

In accordance with an aspect of the present invention, there is provided a method for fabricating a capacitor, comprising the steps of: a) forming a Pt alloy layer, as a bottom electrode, electrically being in contact with an active region of a semiconductor substrate; b) oxidizing a surface of the Pt alloy layer to form a conductive oxide layer; c) forming a dielectric layer on the conductive oxide layer; and d) forming a top electrode on the dielectric layer.

### BRIEF DESCRIPTION OF THE DRAWINGS

The above and other objects and features of the instant invention will become apparent from the following description of preferred embodiments taken in conjunction with the accompanying drawings, in which:

FIG. 1 is a cross-sectional view showing a capacitor according to the prior art; and

FIGS. 2A to 2G are cross-sectional view showing a process for fabricating a capacitor according to the present invention.

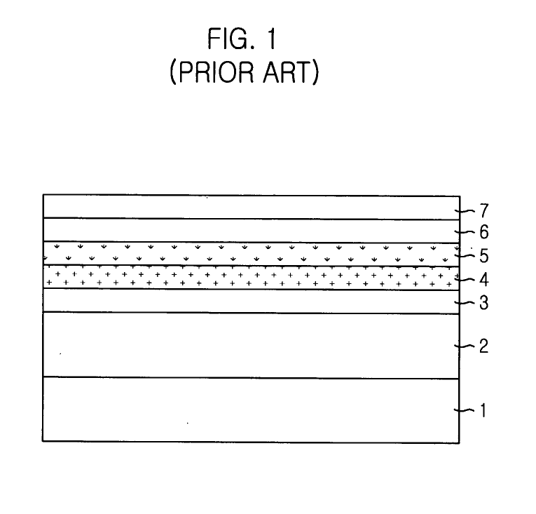

### DETAILED DESCRIPTION OF THE PREFERRED EMBODIMENTS

Hereinafter, a method for fabricating a capacitor according to the present invention will be described in detail referring to the accompanying drawings.

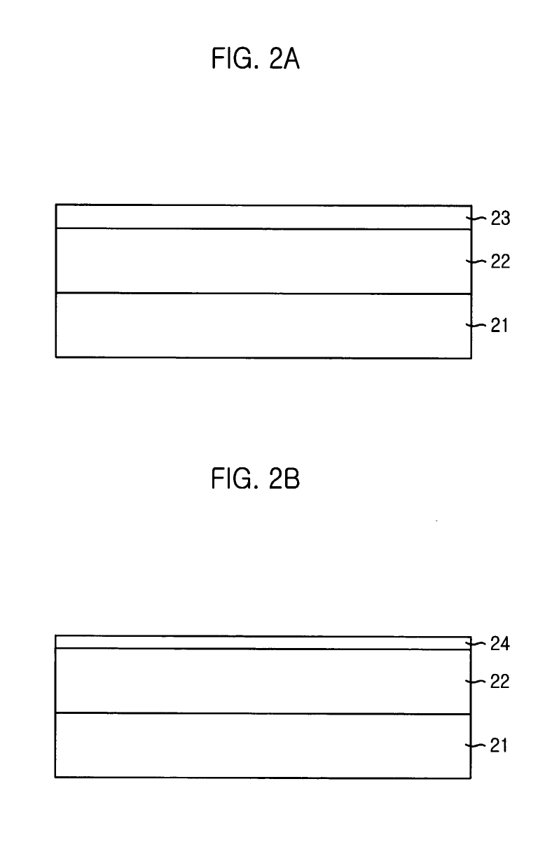

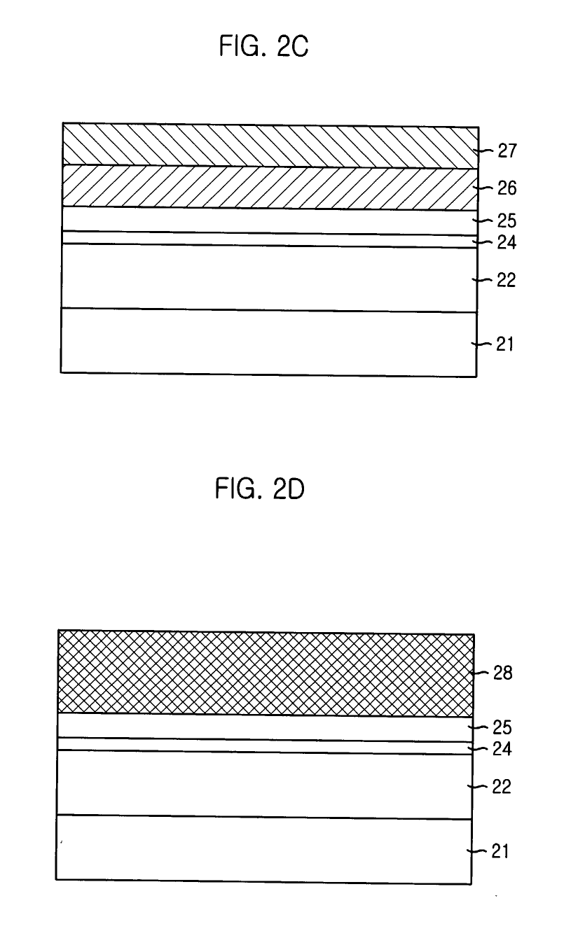

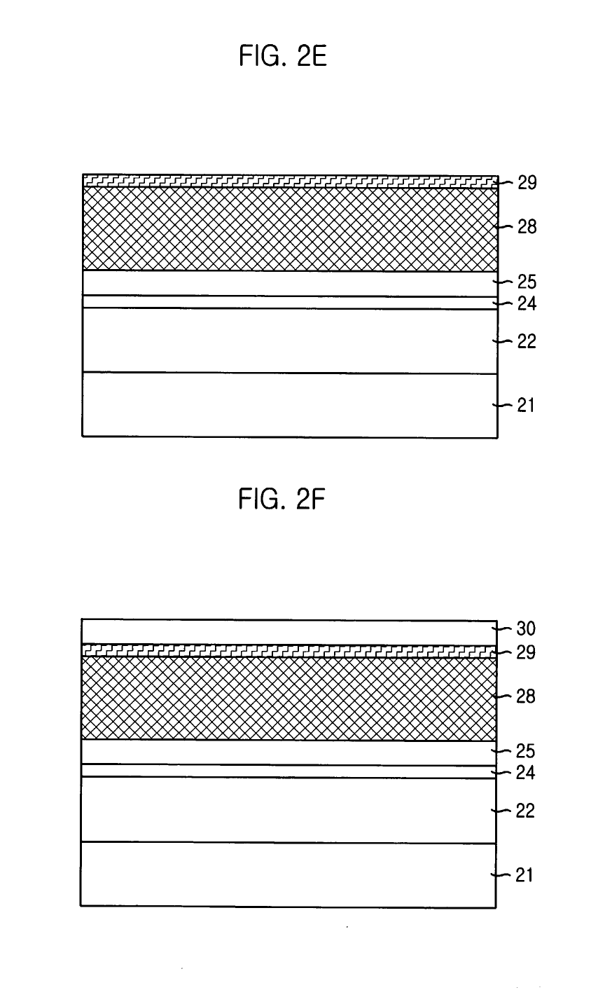

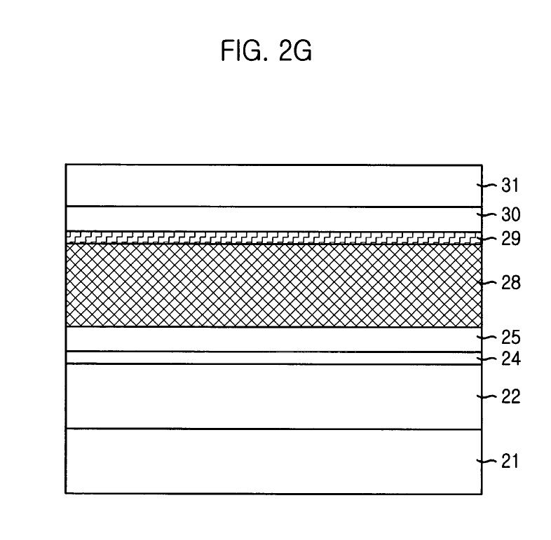

Referring to FIG. 2A, a polysilicon 22 is deposited on a semiconductor substrate 21 and Ti 23 is deposited by an ionized metal plasma physical vapor deposition (PVD) technique or a CVD technique at a thickness of about 100 Å to 500 Å to form an Ohmic contact on the polysilicon layer 22.

Referring to FIG. 2B, a titanium suicide layer 24 is formed by a rapid thermal process at an ambient of a nitrogen gas or a NH₃ gas and at a temperature of about 650° C. to 800° C. for 30 to 180 seconds. Non-reacted Ti is removed by a wet etching process.

Referring to FIG. 2C, a titanium nitride layer 25 is formed as a diffusion barrier layer to protect a reaction between a plug and a bottom electrode. A first bottom electrode 26 is formed with Ru or Ir, which its oxide is also conductive material, by using a metal-organic chemical vapor deposition technique at a low temperature, which the diffusion barrier does not oxidize, and at a thickness of about 100 Å and 500 Å. A second bottom electrode 27 is formed by a Pt layer, which has a good leakage current characteristic due to a large difference between a work functions of the high dielectric material and the Pt layer, by using a PVD technique, a CVD technique or an electric plating technique on the first bottom electrode 26.

Referring to FIG. 2D, the first bottom electrode 26 and the second bottom electrode 27 are alloyed as Ru-Pt or Ir-Pt by a rapid thermal process so that an alloy bottom electrode 28 is formed. The rapid thermal process is carried out at a temperature of 500° C. to 700° C. for 30 seconds to 180 seconds.

Also, the alloy bottom electrode 28 can be formed at one step by a CVD technique using a cocktail source, which is a mixture gas of two or more metal organic sources, including Pt and Ir or Ru or a sputtering technique using an alloy sputtering target including Pt and Ir or Ru. At this time, an Ir mole fraction or a Ru mole fraction which is a mole fraction of the first bottom electrode 26 in the alloy bottom electrode 28, is from 1% to 50%.

Referring to FIG. 2E, a plasma treatment process is carried out for the alloy bottom electrode 28 at an ambient of a O₂ gas or a N₂ gas so that a thin conductive oxide layer 29, such as a Pt—O layer or a RuOₓ layer. The plasma treatment process is carried out at a power of 0.1 kW to 2 kW and at a temperature of about 300° C. to 500° C. for 30 seconds to 180 seconds. The conductive oxide layer 29 is to protect an oxygen diffusion of a dielectric layer.

Referring to FIG. 2F, a dielectric layer 30 of a capacitor is formed by a metal organic CVD technique, an ALD technique or a metal organic deposition technique at a thickness of 100 Å to 2000 Å. The dielectric layer 31 is formed with Ta₂O₅, TaON, STO, BST or the like in the DRAM or PZT, SBT, SBTN, BLT or the like in the FeRAM.

A rapid thermal process or a furnace thermal treatment process is carried out for crystallization of the dielectric layer 30. At this time, the rapid thermal process is carried out at a temperature of about 500° C. to 800° C. for 30 to 180 seconds and the furnace thermal treatment process is carried out at a temperature of about 450° C. to 700° C. for 10 minutes to 30 minutes.

Referring to FIG. 2G, a top electrode 31 is formed with noble metal by a metal organic CVD technique or an ALD technique on the dielectric layer 30.

The method for fabricating the capacitor according to the present invention can be applied to a concave structure capacitor, a stacked structure capacitor or a cylinder capacitor.

As the bottom electrode is formed with the alloy including Pt and the conductive oxide is formed by oxidizing the surface of the bottom electrode according to the present invention, a temperature for crystallizing the high dielectric layer or the ferroelectric layer can increase over 600° C., which is a temperature enough to obtain a desired capacitance.

While the present invention has been described with respect to the particular embodiments, it will be apparent to those skilled in the art that various changes and modifications may be made without departing from the spirit and scope of the invention as defined in the following claims.

What is claimed:

1. A method for fabricating a capacitor, comprising the steps of:
a) forming a Pt alloy layer, as a bottom electrode, electrically being in contact with an active region of a semiconductor substrate;
b) oxidizing a surface of the Pt alloy layer to form a conductive oxide layer;
c) forming a dielectric layer on the conductive oxide layer; and
d) forming a top electrode on the dielectric layer.

2. The method as recited in claim 1, wherein the step a) includes the steps of:
a) forming a metal layer;
b) forming a Pt layer on the metal layer; and
c) performing a thermal treatment process to form the Pt alloy layer of the metal layer and the Pt layer.

3. The method as recited in claim 2, wherein the thermal treatment process is carried out by a rapid thermal process.

4. The method as recited in claim 3, wherein the rapid thermal process is carried out at an ambient of an O₂ gas or a N₂ gas and at a temperature of 500° C. to 700° C. for 30 seconds to 180 seconds.

5. The method as recited in claim 2, wherein the Pt layer is formed by a CVD technique, a PVD technique or an electric plating technique.

6. The method as recited in claim 2, wherein the metal layer is a ruthenium (Ru) layer or an iridium (Ir) layer.

7. The method as recited in claim 2, wherein the metal layer is formed at a thickness of 100 Å to 500 Å.

8. The method as recited in claim 1, wherein the Pt alloy is an alloy of Pt and Ru or an alloy of Pt and Ir.

9. The method as recited in claim 8, wherein the bottom electrode is formed by a sputtering technique using a sputtering target including the Pt alloy.

10. The method as recited in claim 9, wherein a mole fraction of Ru or Ir in the Pt alloy is from 1% to 50%.

11. The method as recited in claim 8, wherein the bottom electrode is formed by a CVD technique using a cocktail source including the Pt alloy.

12. The method as recited in claim 11, wherein a mole fraction of Ru or Ir in the cocktail source is from 1% to 50%.

13. The method as recited in claim 1, wherein the conductive oxide layer is formed by a plasma treatment process at an ambient of an oxygen gas or a nitrogen gas, at a power of 0.1 kW to 2 kW and at a temperature of 300° C. to 500° C. for 30 seconds to 180 seconds.

14. The method as recited in claim 1, further comprising a step of performing a thermal treatment process for crystallization of the dielectric layer.

15. The method as recited in claim 14, wherein the thermal treatment process is carried out by a rapid thermal process at a temperature of 500° C. to 800° C. for 30 seconds to 180 seconds.

16. The method as recited in claim 14, wherein the thermal treatment process is carried out by a furnace thermal treatment process at a temperature of 450° C. to 700° C. for 10 minutes to 30 minutes.
